(19) United States
(12) Patent Application Publication
(10) Pub. No.: US 2019/0258157 A1
(43) Pub. Date: Aug. 22, 2019

(54) PHOTOLITHOGRAPHY SYSTEM AND METHOD INCORPORATING A PHOTOMASK-PELLICLE APPARATUS WITH AN ANGLED PELLICLE

(71) Applicant: GLOBALFOUNDRIES INC., GRAND CAYMAN (KY)

(72) Inventors: Yulu Chen, West Sand Lake, NY (US); Oktawian Sobieraj, Ballston Lake, NY (US); SherJang Singh, Clifton Park, NY (US)

(73) Assignee: GLOBALFOUNDRIES INC., GRAND CAYMAN (KY)

(21) Appl. No.: 15/902,544

(22) Filed: Feb. 22, 2018

(51) Int. Cl. G03F 1/64; G03F 1/22; G03F 7/20; H01L 21/31

(52) U.S. Cl. CPC G03F 1/64; H01L 21/31; G03F 7/70983; G03F 1/22

(57) ABSTRACT

Disclosed is a photolithography (e.g., extreme ultraviolet (EUV) photolithography) system that incorporates a photomask-pellicle apparatus with an angled pellicle. The apparatus includes a photomask structure and a pellicle structure that is mounted on the photomask structure. The pellicle is essentially transparent to a given-type radiation (e.g., EUV radiation), is essentially reflective to out-of-band (OOB) radiation, and is positioned at an angle relative to the photomask. When radiation is directed toward the photomask-pellicle apparatus during a photolithographic exposure process, beams that are reflected and diffracted off of the patterned surface of the photomask structure are directed toward a target semiconductor wafer and beams that are reflected and diffracted off of the pellicle are directed away from the target semiconductor wafer. Aiming the OOB radiation away from the target semiconductor wafer improves imaging quality by minimizing the negative impact of OOB radiation. Also disclosed is an associated photolithography method.

### BACKGROUND

### Field of the Invention

The present invention relates to photolithography and, particularly, to a photolithography system and method incorporating a photomask-pellicle configured for improved imaging.

### Description of Related Art

Photolithography techniques are used to pattern features on semiconductor wafers during integrated circuit (IC) chip manufacturing. Advances in photolithography have, in part, enabled device scaling. Currently, extreme ultraviolet (EUV) photolithography is poised to complement and eventually replace conventional deep ultraviolet (DUV) photolithography as the key enabler for continued scaling due to the significantly smaller illumination wavelength (λ) used, which has the potential to provide enhanced patterning resolution and lower process complexity, among other benefits. For example, EUV photolithography techniques employing EUV radiation with a wavelength (λ) of 13.5 nm may be used to achieve a less than 15 nm half pitch resolution at a single exposure, whereas DUV photolithography techniques employ DUV radiation with a wavelength (λ) of 193 nm in order to achieve a minimum 40 nm half pitch resolution at single exposure. However, one problem currently associated with EUV photolithography is that light sources that are capable of generating radiation with the desired EUV wavelength (e.g., a 13.5 nm wavelength) for an EUV photolithographic exposure process also simultaneously generate radiation with out-of-band (OOB) wavelengths (i.e., with wavelengths outside the EUV wavelength band of 11-14 nm). Unfortunately, exposure to this OOB radiation can negatively impact image quality.

### SUMMARY

In view of the foregoing, disclosed herein are embodiments a photolithography system (e.g., an extreme ultraviolet (EUV) photolithography system) that incorporates a photomask-pellicle apparatus for use during a photolithographic exposure process where radiation from a light source is reflected and diffracted off a photomask and back toward a target semiconductor wafer. The photomask-pellicle apparatus can include a photomask structure and a pellicle structure (i.e., a pellicle adhered to a frame) that is mounted on the photomask structure. The pellicle can be essentially transparent to a given-type radiation (e.g., EUV radiation), can be essentially reflective to out-of-band (OOB) radiation, and can be positioned at an angle relative to the photomask structure, as opposed to parallel to the photomask structure. When radiation is directed toward the photomask-pellicle apparatus by a light source during a photolithographic exposure process, any beams that are reflected and diffracted off of the pellicle will be aimed away from a target semiconductor wafer. Aiming the OOB radiation away from the target semiconductor wafer can improve imaging quality by minimizing the negative impact of the OOB radiation (e.g., by minimizing feature profile degradation as well as the black border (BB) effect). Additionally, any EUV radiation that is reflected and diffracted off of the pellicle will also be aimed way from the target semiconductor wafer, thereby improving imaging quality by, for example, minimizing flare. Also disclosed herein are embodiments of a photolithography method.

More particularly, disclosed herein are embodiments of a photomask-pellicle apparatus for use during a photolithographic exposure process (e.g., an extreme ultraviolet (EUV) photolithographic exposure process) where radiation from a light source is reflected and diffracted off a patterned surface of a photomask structure toward a target semiconductor wafer.

Generally, in each of the embodiments, the apparatus can include a photomask structure and a pellicle structure. The photomask structure can include a center portion with a patterned surface. The photomask structure can also include an edge portion that is adjacent to the periphery of the center portion (i.e., that borders the center portion) and that has a planar surface. The pellicle structure includes a pellicle frame; and a pellicle attached to the pellicle frame. The pellicle can be a planar sheet that is less reflective to (i.e., more transparent to) a first-type radiation than a second-type radiation that is different from the first-type radiation. Additionally, the pellicle frame can be mounted on the planar surface of the photomask structure with the pellicle covering the patterned surface of the photomask structure and being angled relative to the planar surface of the photomask structure.

With this configuration, the photomask-pellicle apparatus ensures that, when a light source used during a photolithography exposure process includes both the first-type radiation and the second-type radiation, first beams of the first-type radiation will generally pass through the pellicle and be reflected and diffracted off of the patterned surface of the photomask structure heading in a range of first directions (e.g., toward a target semiconductor wafer) and second beams of the second-type radiation will generally be reflected and diffracted off of the pellicle in a range of second directions that is different from the range of first directions (e.g., away from the target semiconductor wafer).

More specifically, the apparatus can include a photomask structure and a pellicle structure. The photomask structure can include a center portion with a patterned surface. The photomask structure can also include an edge portion that is adjacent to the periphery of the center portion (i.e., that borders the center portion) and that has a planar surface. The pellicle structure includes a pellicle frame; and a pellicle attached to the pellicle frame. The pellicle can be a planar sheet that is essentially transparent to a first-type radiation, namely, extreme ultraviolet (EUV) radiation and that is essentially reflective to a second-type radiation that is different from the first-type radiation (i.e., out-of-band (OOB) radiation or, more particularly, radiation that is outside the EUV radiation wavelength band). The pellicle frame can be mounted on the planar surface of the photomask structure with the pellicle covering the patterned surface and being angled relative to the planar surface of the photomask structure.

The tilt angle of the pellicle relative to the planar surface of the photomask structure can be such that when, during a photolithographic exposure process, a light source generates first beams of the first-type radiation and second beams of the second-type radiation, the first beams and the second beams will ultimately head in different directions. Specifically, during a photolithographic exposure process, radiation from a light source can be aimed toward the photomask-pellicle apparatus and can include both first beams of the first-type radiation and second beams of the second-type radiation. Each of the beams of radiation from the light source (including each first beam of the first-type radiation and each second beam of the second-type radiation) will be aimed toward the photomask-pellicle apparatus. However, given a range of initial beam angles of all of the beams of radiation (regardless of type) output from the light source and given the tilt angle of the pellicle relative to the planar surface of the photomask structure, each of the beams will be oriented: (a) at some first angle of incidence within a range of first angles of incidence relative to the planar surface of the photomask structure; and (b) at some second angle of incidence within a range of second angles of incidence relative to the pellicle. It should be noted that the mid-point or average of the range of first angles of incidence is referred to herein as the primary (or chief) first angle of incidence relative to the planar surface of the photomask structure. Similarly, the mid-point or average of the range of second angles of incidence is referred to herein as the primary (or chief) second angle of incidence relative to the pellicle.

Additionally, given that the pellicle is essentially transparent to the first-type radiation and essentially reflective to the second-type radiation, most of the first beams (EUV beams) will pass through the pellicle, head toward the patterned surface with a range of first angles of incidence relative to the planar surface of the photomask structure, be reflected and diffracted off of the patterned surface with a range of first angles of reflection and diffraction, will pass back through the pellicle and head in a range of first directions (e.g., toward a target semiconductor wafer), whereas most of the second beams (OOB beams) will head toward the pellicle with a range of second angles of incidence relative to the pellicle, be reflected and diffracted off of the pellicle with a range of second angles of reflection and head in a range of second directions that is different from the range of first directions (e.g., away from the target semiconductor wafer). Additionally, if the pellicle is not fully transparent to all first beams, any first beams that are reflected and diffracted off of the pellicle will similarly head off in the range of second directions (e.g., away from the target semiconductor wafer).

The tilt angle of the pellicle can be predetermined in order to ensure the primary first direction of any beams reflected and diffracted off of the patterned surface of the photomask structure and the primary second direction of any beams reflected and diffracted off of the pellicle are non-parallel and, ideally, to ensure that there is little to no overlap between the range of first directions and the range of second directions. In one embodiment where the range of first angles of incidence is 1 to 11 degrees (or, more particularly, 1.3 to 10.7 degrees) and the primary first angle of incidence is 6 degrees, the tilt angle of the pellicle relative to the planar surface of the photomask structure can be, for example, at least 5 degrees to ensure that the primary first direction of any beams reflected and diffracted off of the patterned surface of the photomask structure and the primary second direction of any beams reflected and diffracted off of the pellicle are non-parallel and further to ensure there is no overlap between the range of first directions and the range of second directions.

It should be noted than in the above-described embodiments any suitable technique could be used to ensure that the pellicle is angled relative to the planar surface of the photomask structure. For example, the pellicle frame itself could be designed to achieve the desired tilt angle. Alternatively, studs or shims could be used (e.g., between the planar surface of the photomask and the pellicle frame and/or between the pellicle frame and the pellicle) to achieve the desired tilt angle.

Also disclosed herein are embodiments of a photolithography method (e.g., an extreme ultraviolet (EUV) photolithography method) that can be performed using the photolithography system. The method embodiments can include providing a photomask structure and also providing a pellicle structure. The photomask structure can have a center portion with a patterned surface. The photomask structure can further have an edge portion that is adjacent to the periphery of the center portion (i.e., bordering the center portion) and that has a planar surface. The pellicle structure can include a pellicle frame; and a pellicle attached to the pellicle frame. The pellicle can be a planar sheet that is less reflective to (i.e., more transparent to) a first-type radiation than a second-type radiation that is different from the first-type radiation. For example, the pellicle can be essentially transparent to the first-type radiation (e.g., extreme ultraviolet (EUV) radiation) and essentially reflective to the second-type radiation (e.g., out-of-band (OOB) radiation or, more particularly, radiation that is outside the EUV radiation wavelength band).

The method embodiments can further include mounting the pellicle structure on the planar surface of the photomask structure to form a photomask-pellicle apparatus with the pellicle covering the patterned surface and being angled relative to the planar surface of the photomask structure (i.e., at a tilt angle relative to the planar surface). A photolithographic exposure process can then be performed using the photomask-pellicle apparatus and a light source that generates first beams of the first-type radiation (e.g., of the EUV radiation) and second beams of the second-type radiation (e.g., of the OOB radiation). During this photolithographic exposure process, the tilt angle of the pellicle relative to the planar surface of the photomask structure can be such that, when radiation from the light source is aimed at the photomask-pellicle apparatus, the first beams (e.g., the EUV radiation beams) and second beams (e.g., the OOB radiation beams) will ultimately head in different directions. That is, during a photolithographic exposure process, radiation from a light source can be aimed toward the photomask-pellicle apparatus and can include both first beams of the first-type radiation and second beams of the second-type radiation. However, given a range of initial beam angles of the all beams of radiation (regardless of type) output from the light source and given the tilt angle of the pellicle relative to the planar surface of the photomask structure, each of the beams will be oriented: (a) at some first angle of incidence within a range of first angles of incidence relative to the planar surface of the photomask structure; and (b) at some second angle of incidence within a range of second angles of incidence relative to the pellicle. It should be noted that the mid-point or average of the range of first angles of incidence is referred to herein as the primary (or chief) first angle of incidence relative to the planar surface of the photomask structure. Similarly, the mid-point or average of the range of second angles of incidence is referred to herein as the primary (or chief) second angle of incidence relative to the pellicle.

Additionally, given that the pellicle is essentially transparent to the first-type radiation and essentially reflective to the second-type radiation, most of the first beams (EUV beams) will pass through the pellicle, head toward the patterned surface with a range of first angles of incidence relative to the planar surface of the photomask structure, be reflected and diffracted off of the patterned surface with a range of first angles of reflection, will pass back through the pellicle and head in a range of first directions (e.g., toward a target semiconductor wafer), whereas most of the second beams (OOB beams) will head toward the pellicle with a range of second angles of incidence relative to the pellicle, be reflected and diffracted off of the pellicle with a range of second angles of reflection and head in a range of second directions that is different from the range of first directions (e.g., away from the target semiconductor wafer). Additionally, if the pellicle is not fully transparent to all first beams, any first beams that are reflected and diffracted off of the pellicle will similarly head off in the range of second directions (e.g., away from the target semiconductor wafer).

The method embodiments can further include predetermining the tilt angle, before the pellicle structure is mounted on the photomask structure, in order to ensure that the primary first direction of any beams reflected and diffracted off of the patterned surface of the photomask structure and the primary second direction of any beams reflected and diffracted off of the pellicle are non-parallel and, ideally, to ensure that there is little to no overlap between the range of first directions and the range of second directions. In one exemplary embodiment, when the range of first angles of incidence is 1 to 11 degrees (or, more particularly, 1.3 to 10.7 degrees), and the primary first angle of incidence is 6 degrees, and a tilt angle of at least 5 degree will ensure that the primary first direction of any beams reflected and diffracted off of the patterned surface of the photomask structure and the primary second direction of any beams reflected and diffracted off of the pellicle will be non-parallel and will further ensure that there is no overlap between the range of first directions and the range of second directions.

In the above-described structure and method embodiments, by ensuring that beams of radiation that are reflected and diffracted off of the pellicle (including primarily second beams of the second-type radiation and, possibly, some first beams of the first-type radiation) will head in different directions than beams of radiation that pass through the pellicle and are reflected and diffracted off of the patterned surface of the photomask structure (including primarily first beams of the first-type radiation and, possible, some second beams of the second-type radiation), any negative impact to the photosensitive layer that would otherwise be caused by such radiation is minimized and imaging quality is improved. For example, in EUV photolithography, aiming the OOB radiation and, particularly, OOB radiation with wavelengths that are 14 nm or higher away from the target semiconductor wafer improves imaging quality by: (a) minimizing photosensitive layer height loss and, thereby minimizing feature profile degradation; and (b) minimizing the black border (BB) effect (i.e., minimizing the amount of light reflected and diffracted off pattern-free dark areas into neighboring die areas) and, thereby minimizing critical dimension fails and improving contrast at the die edges in the resulting pattern. Additionally, aiming any EUV radiation that is reflected and diffracted directly off of the pellicle improves imaging quality by, for instance, minimizing flare.

### BRIEF DESCRIPTION OF THE SEVERAL VIEWS OF THE DRAWINGS

The present invention will be better understood from the following detailed description with reference to the drawings, which are not necessarily drawn to scale and in which:

FIG. 1 is a schematic diagram illustrating an embodiment of a disclosed photolithography system, where the photomask-pellicle apparatus includes a pellicle that is angled relative to the photomask and that reflects out-of-band radiation;

FIGS. 2A-2B are illustrations of radiation beams during a photolithographic exposure process performed using the photolithography system of FIG. 1;

FIGS. 3A-3B are different cross-section diagrams of an embodiment of the photomask-pellicle apparatus;

FIGS. 4A-4B are different cross-section diagrams of another embodiment of the photomask-pellicle apparatus;

FIGS. 5A-5B are different cross-section diagrams of yet another embodiment of the photomask-pellicle apparatus;

FIG. 6 is a flow diagram illustrating an embodiment of a disclosed photolithography method;

FIG. 7 is a schematic diagram illustrating a photolithography system, where the photomask-pellicle apparatus includes a pellicle that is parallel to the photomask;

FIG. 8 is a schematic diagram illustrating a photolithography system, where the photomask-pellicle apparatus includes a pellicle that is parallel to the photomask and that reflects out-of-band radiation; and

FIG. 9 is an illustration of radiation beams during a photolithographic exposure process performed using the photolithography system of FIG. 8.

### DETAILED DESCRIPTION

As mentioned above, one problem currently associated with EUV photolithography is that light sources that are capable of generating radiation with the desired EUV wavelength (e.g., a 13.5 nmλ) for an EUV photolithographic exposure process also simultaneously generate radiation with out-of-band (OOB) wavelengths (i.e., with wavelengths outside the EUV wavelength band of 11-14 nm). Unfortunately, this OOB radiation can negatively impact pattern quality.

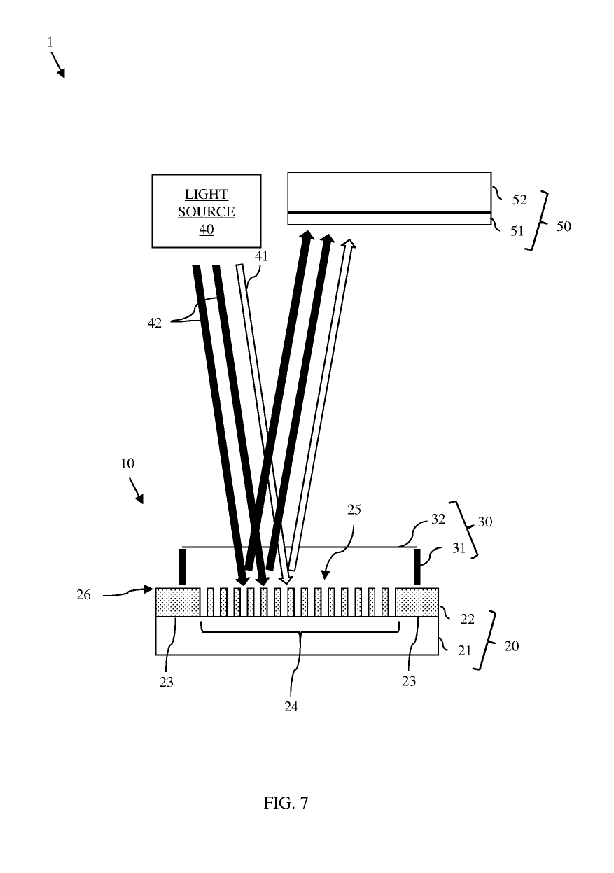

More specifically, FIG. 7 is a schematic diagram illustrating an exemplary EUV photolithography system 1 that includes a photomask-pellicle apparatus 10, a light source 40 and a target semiconductor wafer 50.

The photomask-pellicle apparatus 10 includes a photomask structure 20. The photomask structure 20 includes a substrate 21, which includes a base layer (e.g., a low thermal expansion material layer) and a multilayer stack on the base layer. The multilayer stack includes alternating layers of high and low atomic number materials (i.e., EUV mirrors), which form a Bragg reflector for guiding and shaping EUV photons. The photomask structure 20 further includes a light absorber layer 22 on top of the multi-layer stack. The light absorber layer 22 is patterned with shapes corresponding to desired circuit features such that the photomask structure 20 has a center portion 24 with a patterned surface 25 and an edge portion 23, which is adjacent to the periphery of the center portion (i.e., which borders the center portion 24) and which has a planar surface 26. Those skilled in the art will recognize that if particles (e.g., dust, etc.) fall onto the patterned surface 25 of the photomask structure 20 prior or during a photolithographic exposure process, those particles can cause imaging defects. In order to prevent such particle-induced imaging defects, the photomask-pellicle apparatus 10 includes a protective structure and, particularly, a pellicle structure 30 mounted on the photomask structure 20. The pellicle structure 30 includes pellicle 32 (e.g., a strong and planar sheet) that is attached to a pellicle frame 31. The pellicle frame 31 is attached to the planar surface 26 of the photomask structure 20 such that the pellicle 32 is parallel to the planar surface 26 and further such that the pellicle 32 covers the patterned surface 25, thereby preventing particles from landing thereon before and/or during a photolithographic exposure process. The specific material(s) used in the pellicle 32 is/are preselected to ensure that the pellicle 32 is essentially transparent to EUV wavelengths and resistant to radiation damage. The standoff distance between the pellicle and the patterned area is on the order of millimeters and many orders of magnitude larger than the typical depth of focus of EUV lithography so that any particles landing on the pellicle will not be imaged onto the wafer.

The light source 40 can generate EUV radiation 41 with a wavelength that is within the EUV wavelength band (e.g., with a 13.5 nm wavelength). In addition to the EUV radiation, the light source 40 also simultaneously generates at least one additional-type radiation 42 with wavelengths that are outside the EUV radiation wavelength band (referred to herein as out-of-band (OOB) wavelengths). During a EUV photolithographic exposure process using this EUV photolithography system 1, radiation (including both the radiation 41 and the OOB radiation 42) will be aimed by the light source 40 towards the patterned surface 25 of the photomask structure 20. The different types of radiation 41 and 42 will travel in essentially the same path. That is, both the EUV radiation 41 and the OOB radiation 42 will pass through the pellicle 32, will be reflected and diffracted off of the patterned surface 25 of the photomask structure 20, and will pass back through the pellicle 32 heading toward (i.e., traveling toward, moving toward, etc.) the target semiconductor wafer 50 and, particularly, toward a photosensitive layer 51 on a feature layer 52 to be patterned.

By exposing the photosensitive layer 51 of the target semiconductor wafer 50 to EUV radiation 41 that is reflected and diffracted off of the patterned surface 25 of the photomask structure 20, the pattern of the etched light absorber layer 22 is transferred into the photosensitive layer 51. After the pattern is transferred into the photosensitive layer 51, it can subsequently be transferred into the feature layer 52 below (e.g., by conventional photosensitive layer development and feature layer etch processes). Unfortunately, currently used photosensitive materials are often sensitive to both EUV and OOB radiation. The OOB radiation can, for example, cause photosensitive layer thickness loss and, thereby, profile degradation. The EUV radiation directly reflected and diffracted from pellicle top surface can cause the same side effects. The OOB radiation can also increase what is known in the art as the black border (BB) effect. Specifically, the patterned surface of the photomask will typically include pattern-free dark areas bordering the patterned die areas. Light reflected and diffracted off of the black borders can overlap edges of neighboring die areas in the photosensitive layer and can impact critical dimensions and contrast of the resulting pattern at the edges.

Various different prior art techniques have been used in an attempt to mitigate the impact of OOB radiation exposure during EUV lithography. These techniques typically focus on attempting to eliminate the generation of radiation with OOB wavelengths by the light source as well as attempts to minimize the sensitivity of the photosensitive layer to the OOB radiation. However, neither solution has been able to completely eliminate the problem.

In view of the foregoing, disclosed herein are embodiments a photolithography system (e.g., an extreme ultraviolet (EUV) photolithography system) that incorporates a photomask-pellicle apparatus for use during a photolithographic exposure process where radiation from a light source is reflected and diffracted off a photomask and back toward a target semiconductor wafer. The photomask-pellicle apparatus can include a photomask structure and a pellicle structure (i.e., a pellicle adhered to a frame) that is mounted on the photomask structure. The pellicle can be essentially transparent to a given-type radiation (e.g., EUV radiation), can be essentially reflective to out-of-band (OOB) radiation, and can be positioned at an angle relative to the photomask structure, as opposed to parallel to the photomask structure. When radiation is directed toward the photomask-pellicle apparatus by a light source during a photolithographic exposure process, any beams that are reflected and diffracted off of the pellicle will be aimed away from a target semiconductor wafer. Aiming the OOB radiation away from the target semiconductor wafer can improve imaging quality by minimizing the negative impact of the OOB radiation (e.g., by minimizing feature profile degradation as well as the black border (BB) effect). Additionally, any EUV radiation that is reflected and diffracted off of the pellicle will also be aimed way from the target semiconductor wafer, thereby improving imaging quality by, for example, minimizing flare. Also disclosed herein are embodiments of a photolithography method.

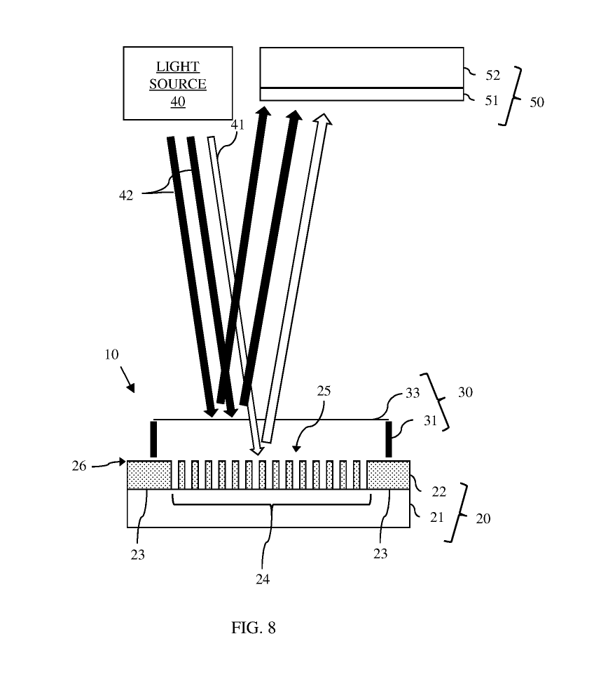

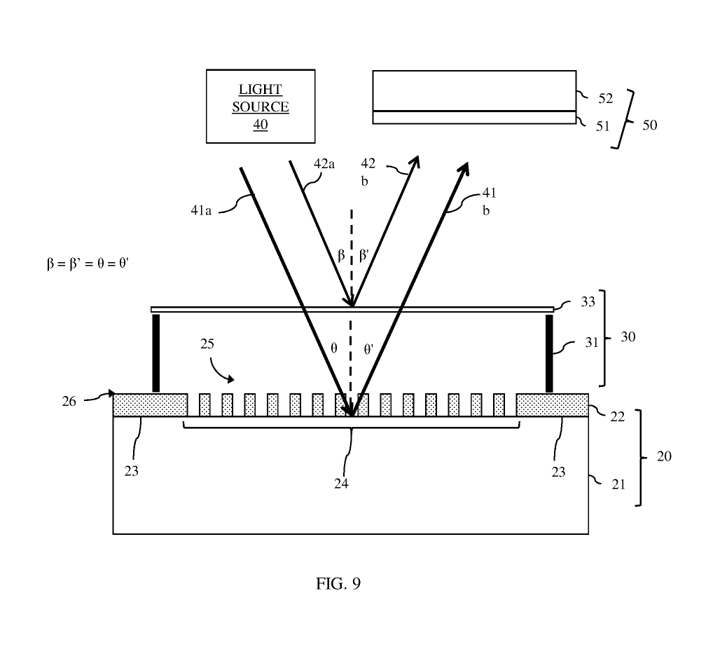

Recently, as illustrated in FIG. 8, the inventors of the present invention considered the use of a pellicle 33 made of a pellicle material, which both transmits EUV radiation 41 (i.e., is essentially transparent to EUV radiation) and reflects OOB radiation 42 (i.e., is essentially reflective to OOB radiation). In this case, during a EUV photolithographic exposure process, the patterned surface 25 of the photomask structure 20 is not exposed (or only minimally exposed) to the OOB 42. However, they found that, even if the pellicle 33 reflects OOB radiation 42 so that the patterned surface 25 is not exposed to (or is only minimally exposed to) the OOB radiation, there may not be significant improvement to imaging quality because the OOB radiation 42 is still directed toward the target semiconductor wafer 50 along with the EUV radiation 41. Specifically, referring to FIG. 9, if the pellicle 33 is parallel to the planar surface 26 of the photomask structure 22 and the light source 40 directs EUV beams and OOB beams toward the patterned surface 25 of the photomask structure 20, a first angle of incidence θ of incident EUV beams 41a relative to the planar surface of the photomask structure 120 will be the same as a second angle of incidence β of incident OOB beams 42a relative to the pellicle 33. Furthermore, since a first angle of reflection β′ of reflected EUV beams 41b, which are reflected and diffracted off of that patterned surface 25, will mirror the first angle of incidence β′ and since a second angle of reflection β′ of reflected OOB beams 42b, which are reflected and diffracted off of the pellicle 33, will mirror the second angle of incidence β′, the reflected EUV beams 41b and the reflected OOB beams 42b will necessarily head (i.e., travel, move, etc.) in the same direction toward the target semiconductor wafer 50. The inventors have determined that, as long as the range of angles of incidence of OOB beams relative to the pellicle and the corresponding range of angles of reflection of the OOB beams toward the photosensitive layer 51 of the target semiconductor wafer 50 are the same as the range of angles of incidence of the EUV beams relative to patterned surface 25 of the photomask structure 20 and the corresponding range of angles of reflection of the EUV beams toward the photosensitive layer 51 of the target semiconductor wafer 50, respectively, then any OOB radiation reflected and diffracted off of the pellicle 33 will have the same detrimental effects on imaging quality as any OOB beams that are reflected and diffracted off of the patterned surface 25 of the photomask structure 20.

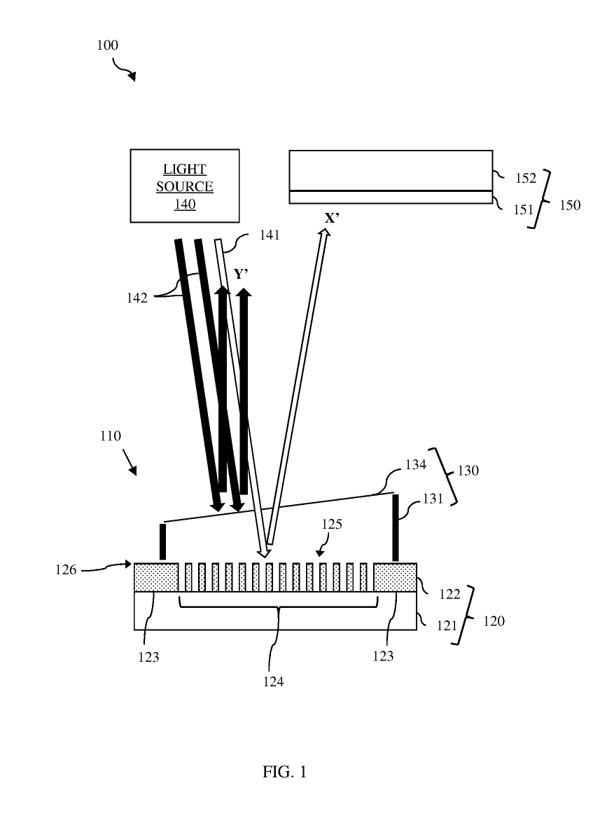

Therefore, referring to FIG. 1, disclosed herein are embodiments of a photolithography system 100 that includes a photomask-pellicle apparatus 110 and a light source 140. FIG. 1 also illustrates a target semiconductor wafer 150 that can be patterned using the photolithography system 100. The photolithography system 100 can be, for example, an extreme ultraviolet (EUV) photolithography system or any other similar system where reflected light from the light source 140 is reflected and diffracted off of the photomask-pellicle apparatus 110 and used to pattern a photosensitive layer 151 on target semiconductor wafer 150 and where the patterned photosensitive layer is then used to pattern a feature layer 152 below the photosensitive layer 151 (e.g., by conventional photosensitive layer development and feature layer etch processes).

Also disclosed herein are embodiments of a photomask-pellicle apparatus 110 that can be incorporated into the photolithography system 100. The photomask-pellicle apparatus 110 can include a photomask structure 120 and a pellicle structure 130.

The photomask structure 120 can include a planar substrate 121 and a patterned layer 122 on the substrate 121. The substrate 121 can include at least a base layer (e.g., a low thermal expansion material layer) and a multilayer stack on the base layer. The multilayer stack can include alternating layers of high and low atomic number materials (referred to herein as EUV mirrors) that form a Bragg reflector for guiding and shaping EUV photons. The photomask structure 120 can further include a patterned layer 122 on top of the substrate 121 and, particularly, on the multi-layer stack. The patterned layer 122 can be a light absorber layer made of a material that absorbs a first-type radiation (e.g., EUV radiation) and can have a patterned center portion and a non-patterned edge portion. The patterned center portion can specifically be patterned (e.g., lithographically patterned and etched) to include shapes that correspond to desired circuit features. Thus, the photomask structure 120 can have a center portion 124 with a patterned surface 125 and Bragg reflector surfaces are exposed at the bottoms of openings in the patterned surface 125. The photomask structure 120 can further have edge portion 123, which is adjacent to the periphery of the center portion 124 (i.e., which borders the center portion 124) and which has a planar surface 126 that is essentially parallel to the planar substrate 121.

The pellicle structure 130 can include a pellicle 134 (e.g., a strong and planar sheet or film). The pellicle 134 can be made of one or more layers of one or more pellicle materials, which are preselected and configured to ensure that the pellicle 134 has specific optical properties. For example, the pellicle material(s) and configuration can be preselected to ensure that the pellicle 134 is less reflective to (i.e., more reflective to) a first-type radiation (e.g., EUV radiation or any other specific type of radiation suitable for use in the photolithography system 100) than a second-type radiation that is different from the first-type radiation (e.g., out-of-band (OOB) radiation). Thus, for example, the pellicle material(s) and configuration can be preselected so that the pellicle 134 is: (a) essentially transparent to the first-type radiation, and (b) essentially reflective to the second-type radiation.

For purposes of this disclosure, the pellicle is essentially transparent to a given-type of radiation if at least 90 percent of beams of that given-type of radiation will pass through the pellicle. Similarly, the pellicle is essentially reflective to a given-type of radiation if at least 90 percent of beams of that given-type of radiation will be reflected and diffracted off of the pellicle. Additionally, for purposes of this disclosure, out-of-band (OOB) radiation refers to radiation that falls outside the wavelength band of another specific-type of radiation. For example, if the first-type radiation is EUV radiation with a wavelength band of 11-14 nm and the second-type radiation is OOB radiation, then the second-type of radiation will include radiation having wavelengths outside the EUV radiation wavelength band of 11-14 or, more particularly, will include radiation that is 14 nm or higher and that tends to negatively impact EUV imaging.

In one exemplary embodiment, the pellicle 134 can be a three-layer sheet including a bottom silicon nitride layer, a polysilicon layer on the bottom silicon nitride layer, and a top silicon nitride layer on the polysilicon layer. The polysilicon layer can be relatively thick (e.g., can have a thickness ranging from 40-50 nm, such as 44 nm). The bottom silicon nitride layer and the top silicon nitride layer can be relatively thin as compared to the polysilicon layer. For example, the bottom and top silicon nitride layers can have thicknesses ranging from 3 to 6 nms, such as 3.8 nm and 5 nm, respectively. It should be understood that this exemplary pellicle configuration is not intended to be limiting and that, alternatively, any suitable pellicle material(s) (e.g., polymer(s), etc.) and configuration could be used as long as the desired optical properties are achieved.

The pellicle structure 130 can further include a pellicle frame 131 (also referred to herein as a support frame). The pellicle frame 131 can be made of an anodized aluminum, which is, optionally, coated with a polymer for ion control. Alternatively, the pellicle frame 131 can be made of a dimensionally stable, polymer material that is compatible with an injection molding process. In any case, the shape of the pellicle frame 131 can correspond to the shape of the pellicle 134 so that the pellicle 134 can be attached to (e.g., adhered to by adhesive, bonded to or otherwise attached to) the top surfaces of the walls of the pellicle frame 131. For example, a square pellicle can have a square frame, a rectangular pellicle can have a rectangular frame, a circular pellicle can have a circular frame, an oval pellicle can have an oval shaped frame, and so on.

The pellicle structure 130 can further be mounted on the photomask structure 120. Specifically, the bottom surfaces of the walls of the pellicle frame 131 can be attached to (e.g., adhered by an adhesive, bonded to, or otherwise attached to) the planar surface 126 of the photomask structure 120 (on the non-patterned edge portion of the patterned layer 122) such that the patterned surface 125 of the photomask structure 120 is bordered by the walls of the pellicle frame 131 and such that the pellicle 134 covers the patterned surface 125. As discussed above, any particles that might fall onto the patterned surface 125 can cause imaging defects. Thus, the pellicle 134 functions as a protective barrier that prevents such particles from landing on the patterned surface 125 before and/or during a photolithographic exposure process. However, instead of being parallel relative to the planar surface 126 (and similarly parallel to the planar substrate 121) as seen in prior art photomask-pellicle apparatuses, the pellicle 134 can be angled in the embodiments of the photomask-pellicle apparatus 110 disclosed herein.

Specifically, the photomask-pellicle apparatus 110 can be configured with an angled pellicle 134 and the specific tilt angle α of this angled pellicle 134 relative to the planar surface 126 of the photomask structure 120 can be predetermined so that when, during a subsequent photolithographic exposure process, the light source 140 of the photolithography system 100 generates first beams 141 of the first-type radiation (e.g., EUV beams) and second beams 142 of the second-type radiation (e.g., OOB beams), the different types of beams will ultimately primarily head in different directions.

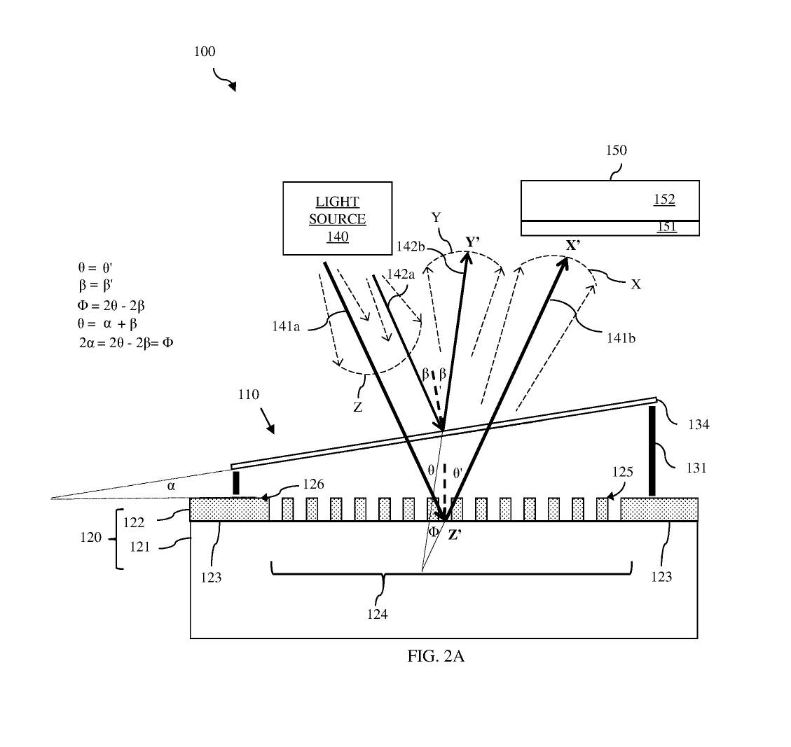

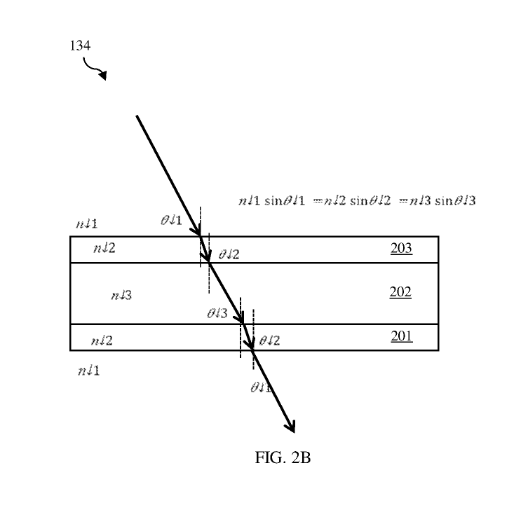

More specifically, referring to FIG. 2A, while a light source 140 could ideally or preferably generate and output radiation of only one-type, current state of the art light sources typically output radiation of multiple different types. For example, the radiation output by the light source 140 can be both first beams of the first-type radiation (e.g., EUV radiation) and second beams of the second-type radiation (e.g., OOB radiation). The light source 140 can be positioned or otherwise adjusted so that beams of radiation (including each incident first beam 141a of the first-type radiation and each incident second beam 142a of the second-type radiation) are generally aimed toward the photomask-pellicle apparatus 110. However, it should be understood that typically beams of radiation output by a light source 140 will head (i.e., travel, move, etc.) in a range Z of initial directions with the primary (or chief) initial direction Z′ being at the midpoint of this range Z toward the photomask-pellicle apparatus 110. Given the range Z of initial directions of the beams output by the light source 140 and given the tilt angle α of the pellicle 134 relative to the planar surface 126, all of the beams will be oriented: (a) at some first angle of incidence within a range of first angles of incidence relative to the planar surface 126 of the photomask structure 120; and (b) at some second angle of incidence within a range of second angles of incidence relative to the pellicle 134. Furthermore, it should be noted that, for purposes of this disclosure, the mid-point of the range of first angles of incidence relative to the planar surface 126 of the photomask structure 120 is referred to herein as the primary (or chief) first angle of incidence θ and the mid-point of the range of second angles of incidence relative to the pellicle 134 is referred to herein as the primary (or chief) second angle of incidence β.

Given that the pellicle 134 is essentially transparent to the first-type radiation, incident first beams 141a of the first-type radiation will primarily pass through the angled pellicle 134 and head toward the patterned surface 125 of the photomask structure 120 with a range of first angles of incidence relative to the planar surface 126 of the photomask structure. Reflected first beams 141b of the first-type radiation will be reflected and diffracted off of the exposed Bragg reflector surfaces within the patterned surface 125 with a range of first angles of reflection, will pass back through the angled pellicle 134 and will head in a range X of first directions toward the target semiconductor wafer 150 and, more particularly, toward the photosensitive layer 151 thereof. Furthermore, a primary first angle of reflection θ′ within the range of first angles of reflection (e.g., at the mid-point of the range of first angles of reflection) will correspond to a primary (or chief) first direction X′ within the range X of first directions (e.g., at the mid-point of the range X of first directions).

Given that the pellicle 134 is essentially reflective to the second-type radiation and angled, incident second beams 142a of the second-type radiation (which are aimed by the light source 140 in the same range Z of initial directions as the incident first beams 141a) will head toward the angled pellicle 134 with a range of second angles of incidence relative to the pellicle 134. As a result, reflected second beams 142b of the second-type radiation will be reflected and diffracted off of the angled pellicle 134 with a range of second angles of reflection that is different from the range of first angles of reflection. Thus, the reflected second beams 142b will head in a range Y of second directions that is different from the range X of first directions (e.g., that is away from the target semiconductor wafer 150). Furthermore, a primary second angle of reflection β′ within the range of second angles of reflection (e.g., at the mid-point of the range of second angles of reflection) will correspond to a primary (or chief) second direction Y′ within the range Y of second directions (e.g., at the mid-point of the range Y of second directions).

It should further be understood that if the pellicle 134 is not transparent to all of the first beams of the first-type radiation (i.e., if not all incident first beams 141a pass through the pellicle 134), then any of the first beams of the first-type radiation that are reflected and diffracted off of the pellicle 134 will similarly head off in the range Y of second directions (e.g., away from the target semiconductor wafer 150).

In the embodiments disclosed herein, the primary first angle of incidence θ will be equal to the chief beam angle at which the light source 140 aims radiation toward the planar surface 126 of the photomask structure 120. Furthermore, the primary first angle of incidence θ and the specific tilt angle α of the angled pellicle 134 relative to the planar surface 126 of the photomask structure 120 can specifically be predetermined to ensure that the primary first direction X′ of any beams reflected and diffracted off of the patterned surface 125 of the photomask structure 120 and the primary second direction Y′ of any beams reflected and diffracted off of the pellicle 134 are not parallel and, ideally, to ensure that there is little to no overlap between the range X of the first directions of any beams reflected and diffracted off of the patterned surface 125 and the range Y of the second directions of any beams reflected and diffracted off of the pellicle 134 (i.e., to avoid or at least reduce overlap between the ranges of directions), as illustrated.

In one exemplary embodiment, the light source aim beams of radiation in a range of angles off of normal to the planar surface of the photomask structure 120, where the range encompasses approximately 1 degrees (e.g., 1-11 degrees, 1.3-10.7 degrees, etc.) and where the chief beam angle is 6 degrees. Thus, the range of first angles of incidence of beams output from the light source 140 can encompass 10 degrees and the primary first angle of incidence θ′ can be 6 degrees. The goal in setting the tilt angle α of the angled pellicle 134 in this embodiment is to ensure that the primary second direction Y′ of any beams reflected and diffracted off of the pellicle 134 is not parallel to the primary first direction X′ of any beams reflected and diffracted off of the patterned surface 125 of the photomask structure 120 and, ideally, to ensure that there is no overlap between the range X of first directions and the range Y of second directions (i.e., to avoid or at least reduce overlap between the ranges of directions).

Given the law of reflection, which holds that the angle of incidence will be equal to the angle of reflection and further given the rules of basic trigonometry, the following equations would apply to the angles labeled on the photomask-pellicle apparatus 110 shown in FIG. 2A:

θ=θ′, (1)

β=β′, (2)

Φ=2θ−2β, and (3)

θ=α+β (4)

where θ is the primary first angle of incidence, θ′ is the primary first angle of reflection, β is the primary second angle of incidence, and β′ is the primary second angle of incidence, where Φ is the angle between beams reflected and diffracted off of the patterned surface 125 of the photomask structure 120 (i.e., primarily reflected first beams 141b) at the primary first angle of reflection θ′ and beams reflected and diffracted off of the pellicle 134 (i.e., primarily reflected second beams 142b) at the primary second angle of reflection β′, and where a is the tilt angle. Furthermore, given the equations (1)-(4) above, the following equation would be true and could be solved to find the minimum tilt angle α necessary to avoid overlap between the ranges X and Y of directions:

2α=2θ−2β=Φ. (5)

Thus, if the range of the first angles of incidence is 10 degrees, then the specific tilt angle α can be as small as 5 degrees (i.e., α≥5 degrees).

It should be noted that, for purposes of illustration, the beams of radiation are shown in FIG. 2A as passing directly through the thin pellicle 134. Those skilled in the art will recognize that, per Snell's law, light will actually bend as it passes through material. However, as long as the pellicle 134 is planar, light will propagate in the same direction after it passes through the pellicle 134. Thus, as illustrated in FIG. 2B, the pellicle 134 can be configured with multiple layers with varying thicknesses (e.g., a bottom silicon nitride layer 201 of 5 nm, a polysilicon layer 202 of 44 nm on the bottom silicon nitride layer 201 and a top silicon nitride layer 203 of 3.8 nm on the polysilicon layer 202) to ensure that the primary first angle of incidence θ is essentially the same before and after beams of light pass through the pellicle 134 heading toward the patterned surface 125 of the photomask structure 120.

It should be noted than any suitable techniques of forming the pellicle frame 131 and attaching the pellicle 134 to the pellicle frame 131 and/or mounting the pellicle structure 130 to the photomask structure 120 could be used to ensure that the pellicle 134 is angled at the desired tilt angle α relative to the planar surface 126 of the photomask structure 120.

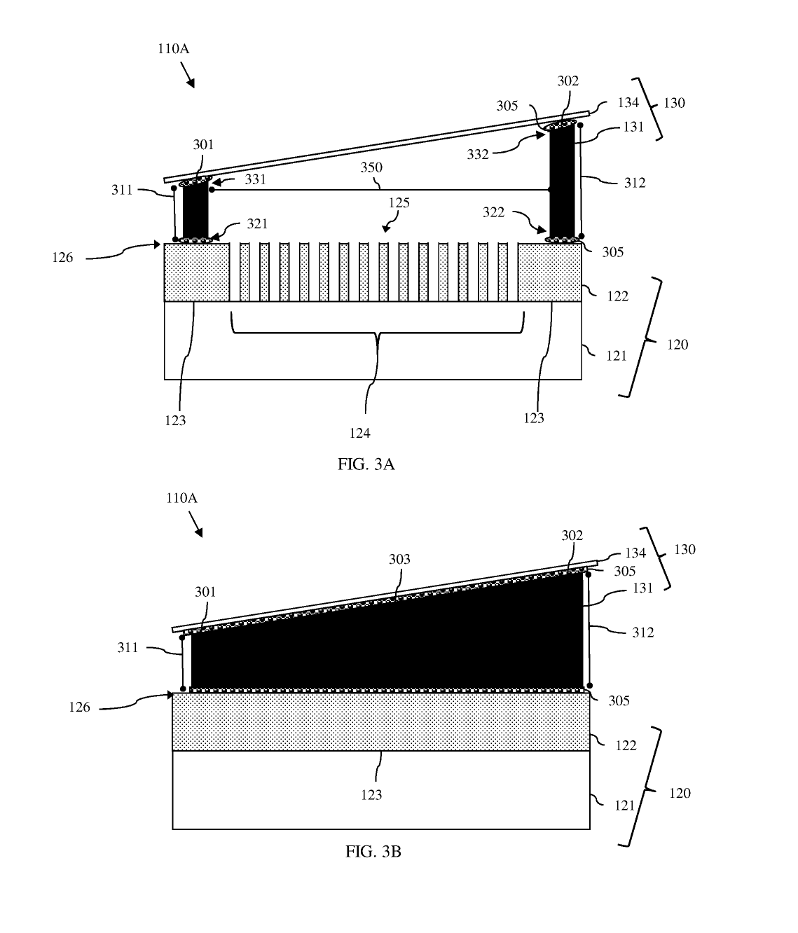

For example, FIGS. 3A-3B show different cross-section views of an exemplary photomask-pellicle apparatus 110A where the pellicle frame 131 is customized and designed so that the pellicle 134 will have a tilt angle that is fixed. Specifically, as shown in FIG. 3A, the pellicle frame 131 can have a first end wall 301 and a second end wall 302 opposite the first end wall 301. The first end wall 301 can have a first height 311, the second end wall 302 can have a second height 312 that is greater than the first height 311, and the first end wall 301 can be separated from the second end wall 302 by a predetermined distance 350 sufficient to ensure that the desired tilt angle α for the pellicle 134 can be achieved. The bottom surfaces 321-322 of the end walls 301-302 can be flat and the top surfaces 331-332 of the end walls 301-302 can be angled and, particularly, can have the desired tilt angle relative to the bottom surfaces. Furthermore, as illustrated in FIG. 3B, opposing sidewalls 303 can extend between the ends walls 301-302. The bottom surfaces of the opposing sidewalls 303 can be flat. Additionally, the heights of the sidewalls 303 can taper downward from the second end wall 302 to the first end wall 301 so that the pellicle 134 can be set on the top of the pellicle frame 131 when the pellicle 134 is placed on the pellicle frame 131 and attached thereto (e.g., by adhesive 305). In this configuration, the pellicle frame 131 can be set on the planar surface 126 of the photomask structure 120 and attached thereto (e.g., by adhesive 305) and the pellicle 134 will be angled relative to the planar surface 126.

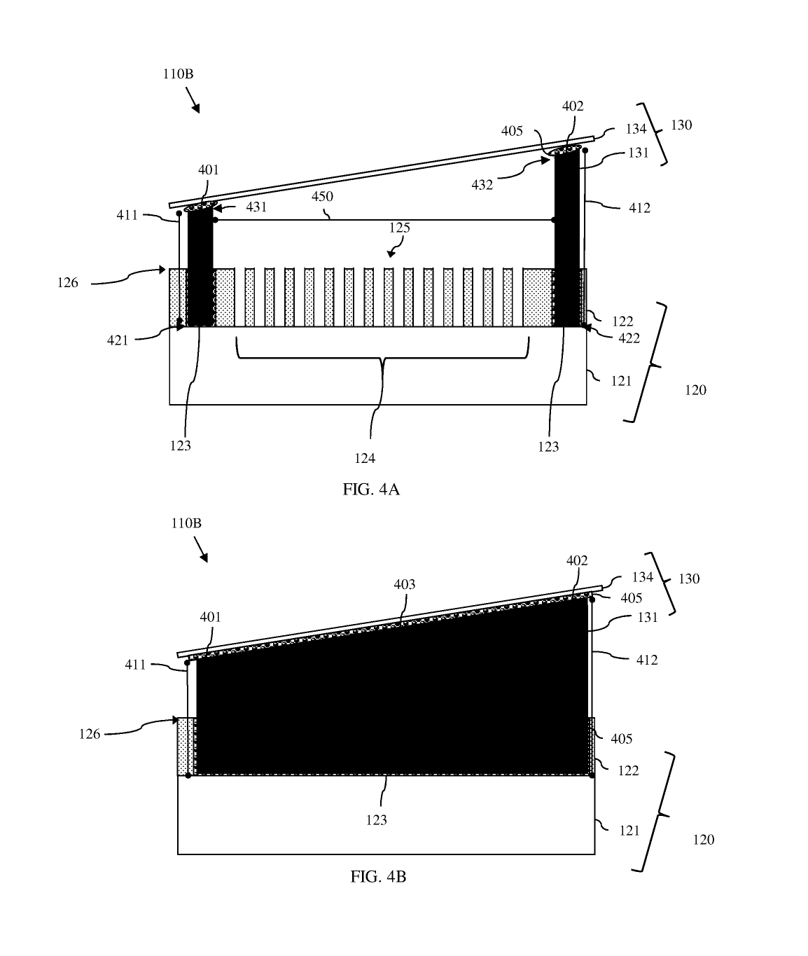

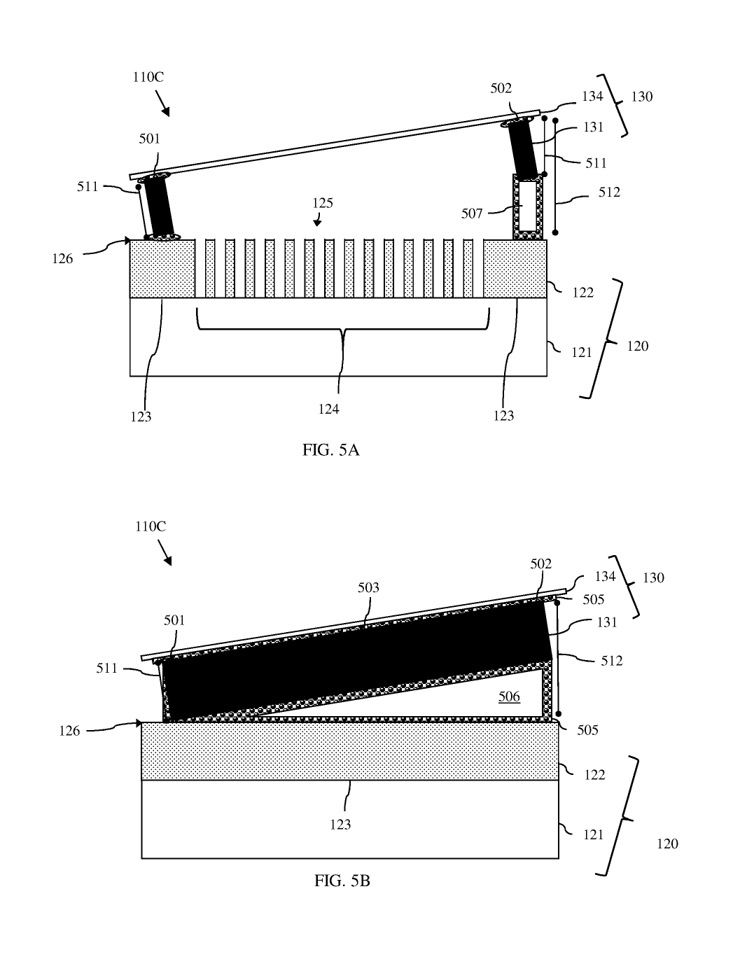

FIGS. 4A-4B show different cross-section views of another exemplary photomask-pellicle apparatus 110B where the pellicle frame 131 is customized and designed so that the pellicle 134 will have a tilt angle that is fixed. Specifically, as shown in FIG. 4A, the pellicle frame 131 can have a first end wall 401 and a second end wall 402 opposite the first end wall 401. The first end wall 401 can have a first height 411, the second end wall 402 can have a second height 412 that is greater than the first height 411, and the first end wall 401 can be separated from the second end wall 402 by a predetermined distance 450 sufficient to ensure that the desired tilt angle α for the pellicle 134 can be achieved. The bottom surface 421-422 of the end walls 401-402 can be flat and the top surfaces 432-432 of the end walls 401-402 can be angled and, particularly, can have the desired tilt angle relative to the bottom surfaces. Furthermore, as illustrated in FIG. 4B, opposing sidewalls 403 can extend between the ends walls 401-402. The bottom surfaces of the opposing sidewalls 403 can be flat. Additionally, the height of the sidewalls 403 can taper downward from the second end wall 402 to the first end wall 401. However, in this case, a groove can be formed in the patterned layer 122 around the edge portion 123. The pellicle frame 131 can be inserted into the groove and attached thereto (e.g., by adhesive 405) such that the pellicle frame 131 is partially embedded in the patterned layer 122 and the pellicle 134 is still angled relative to the planar surface 126.

FIGS. 5A-5B show different cross-section views of another exemplary photomask-pellicle apparatus 110C where a standard pellicle frame is used. That is, the walls 501-503 of the pellicle frame 131 all have the same height 511 and flat top and bottom surfaces. As illustrated, the pellicle 134 can be set on the top of the pellicle frame 131 and attached directly thereto (e.g., by adhesive 505). In this case, the pellicle frame 131 could further be mounted onto the planar surface 126 of the photomask structure 120 using a combination of adhesive 505 and stud(s) 507 and/or shim(s) 506 to raise one side (e.g., the end wall 502) to a new height 512 in order to ensure that the specific tilt angle α for the pellicle 134 is achieved. Alternatively, a combination of adhesive 505 and stud(s) 507 and/or shim(s) 506 could be used when attaching the pellicle 134 to the top of the pellicle frame 131 in order to ensure that the specific tilt angle α for the pellicle 134 is achieved (not shown) and the pellicle frame 131 can be set on the planar surface 126 and attached thereto (e.g., by adhesive 505).

It should be noted that the exemplary structures shown in FIGS. 3A-3B through 5A-5B are not intended to be limiting and that any other suitable structure could be used wherein the pellicle 134 is attached to the pellicle frame 131 and the pellicle frame 131 is mounted on the photomask structure 120 so that the pellicle 134 is angled. For example, alternatively embodiments could include a pellicle frame configured to allow the angle of the pellicle to be selectively adjusted. Furthermore, FIGS. 3A-5B show the walls of the frame (i.e., the opposing end walls and the opposing sidewalls) as being essentially linear. However, as mentioned above, the shape of the pellicle frame could be circular or oval-shaped instead of rectangular or square. Thus, it should be understood that in the case of a circular or oval-shaped pellicle frame the walls of the frame (i.e., the opposing end walls and the opposing sidewalls) would be curved.

In any case, by ensuring that beams of radiation that are reflected and diffracted off of the pellicle 134 (including primarily second beams of the second-type radiation and, possibly, some first beams of the first-type radiation) head in different directions than those beams of radiation that pass through the pellicle 134 and are reflected and diffracted off of the patterned surface 125 of the photomask structure 120 (including primarily first beams of the first-type radiation and, possible, some second beams of the second-type radiation) (as shown in FIG. 2A), each of the above-described photomask-pellicle apparatus embodiments 110A-110C improve imaging quality by minimizing any negative impact to the photosensitive layer 151 that would otherwise be caused by such radiation. For example, in EUV photolithography, aiming the OOB radiation and, particularly, OOB radiation with wavelengths that are 14 nm or higher away from the target semiconductor wafer 150 improves imaging quality by: (a) minimizing photosensitive layer height loss and, thereby minimizing feature profile degradation; and (b) minimizing the black border (BB) effect (i.e., minimizing the amount of light reflected and diffracted off pattern-free dark areas into neighboring die areas) and, thereby minimizing critical dimension fails and improving contrast at the die edges in the resulting pattern. Additionally, aiming any EUV radiation that is reflected and diffracted directly off of the pellicle 134 improves imaging quality by, for instance, minimizing flare.

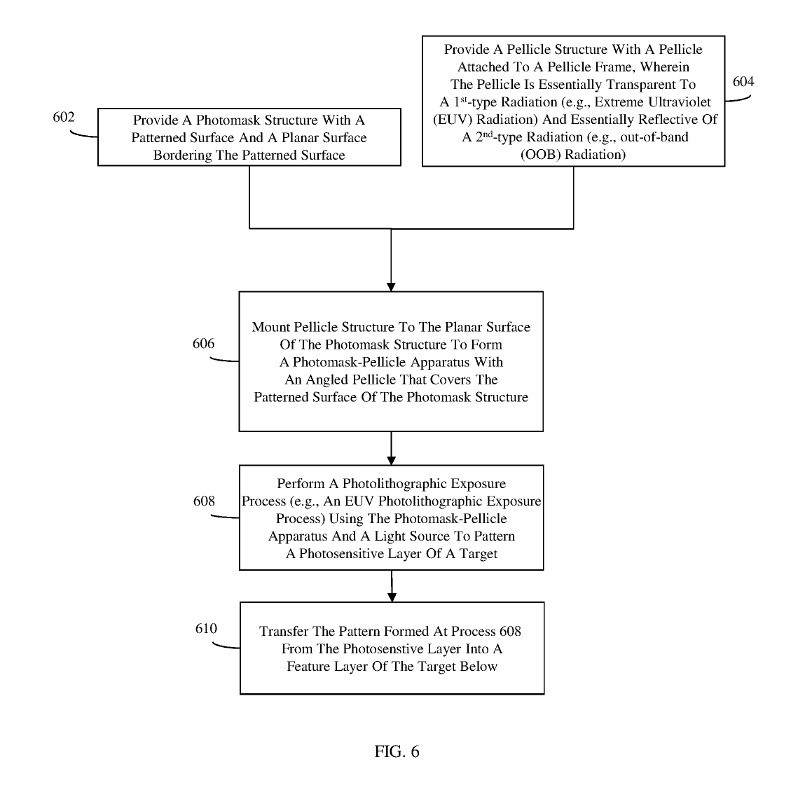

Referring to the flow diagram of FIG. 6, also disclosed herein are embodiments of a photolithography method that can be implemented using, for example, the photolithography system 100 shown in FIGS. 1-2B, including any of the disclosed embodiments of the photomask-pellicle apparatus 110 shown in FIGS. 3A-5B.

Specifically, the method embodiments can include providing a photomask structure 120 (see process 602) and also providing a pellicle structure 130 (see process 604).

As discussed in greater detail above with regard to the structure embodiments, the photomask structure 120 provided at process 602 can include a substrate 121 and a patterned layer 122 on the substrate 121. The patterned layer 122 can have a patterned center portion and a non-patterned edge portion. The patterned center portion can specifically be patterned (e.g., lithographically patterned and etched) to include shapes that correspond to desired circuit features. Thus, the photomask structure 120 can have a center portion 124 with a patterned surface 125 and can further have an edge portion 123, which is adjacent to the periphery of the center portion 124 and which has a planar surface 126 that is essentially parallel to the bottom surface of the substrate 121.

As discussed in greater detail above with regard to the structure embodiments, the pellicle structure 130 provided at process 604 can include a pellicle 134 (e.g., a strong and planar sheet or film). The pellicle 134 can have specific optical properties including being less reflective to (i.e., more transparent to) a first-type radiation than a second type radiation. For example, the specific optical properties of the pellicle 134 can include: (a) being essentially transparent to the first-type radiation (e.g., to EUV radiation or any other specific type of radiation suitable for use in the photolithography system 100) and (b) being essentially reflective to a second-type radiation that is different from the first-type radiation (e.g., an out-of-band (OOB) radiation and, particularly, radiation that is outside the wavelength band of the first-type radiation). For example, if the first-type radiation is EUV radiation with a wavelength band of 11-14 nm, then the second-type radiation can be radiation wavelengths outside the EUV radiation wavelength band of 11-14 or, more particularly, radiation that is 14 nm or higher and that tends to negatively impact EUV imaging. The pellicle structure 130 can further include a pellicle frame 131. It should be noted that exemplary materials and configurations for the pellicle 134 and pellicle frame are described in detail above with regard to the structure embodiments.

The method embodiments can further include mounting the pellicle structure 130 on the photomask structure 120 to form a photomask-pellicle apparatus 110 with an angled pellicle 134 (see process 606). Specifically, the bottom surfaces of the walls of the pellicle frame 131 can be attached to (e.g., adhered by an adhesive, bonded to, or otherwise attached to) the planar surface 126 of the photomask structure 120 (on the non-patterned edge portion of the patterned layer 122) such that the patterned surface 125 of the photomask structure 120 is bordered by the walls of the pellicle frame 131 and such that the pellicle 134 covers the patterned surface 125. As discussed above, any particles that might fall onto the patterned surface 125 can cause imaging defects. Thus, the pellicle 134 can function as a protective barrier that prevents such particles from landing on the patterned surface 125 before and/or during a photolithographic exposure process. However, instead of being parallel relative to the planar surface 126 (and similarly parallel to the bottom surface of the substrate 121) as seen in prior art photomask-pellicle apparatuses, when the pellicle structure 130 is mounted on the photomask structure 120, the pellicle 134 can be angled. Specifically, the pellicle 134 can be angled at a specific tilt angle α relative to the planar surface 126 of the photomask structure 120 and, as discussed in greater detail below, this specific tilt angle can be predetermined.

The method embodiments can further include using a light source 140 and the photomask-pellicle apparatus 110 to perform a photolithographic exposure process (e.g., an EUV photolithographic exposure process) that creates an exposure pattern in a photosensitive layer 151 of a target semiconductor wafer 150 (see process 608). If/when, during this photolithographic exposure process, the light source 140 generates both first beams 141 of the first-type radiation (e.g., EUV beams) and second beams 142 of the second-type radiation (e.g., OOB beams), the first beams and second beams will ultimately primarily head (i.e., travel, move, etc.) in different directions (e.g., toward and away from a target semiconductor wafer, respectively) because of the optical properties and a tilt angle α of the pellicle 134 (see the detailed discussion above regarding FIGS. 2A-2B).

In order to ensure that the first beams of the first-type radiation and the second beams of the second-type radiation primarily head (i.e., travel, move, etc.) in different directions at process 608, the method embodiments can further include, before mounting the pellicle structure 130 on the photomask structure 120 at process 606, predetermining a tilt angle α for the angled pellicle 134 relative to the planar surface 126 of the photomask structure 120 based on a primary first angle of incidence θ (i.e., the chief beam angle at which incident first beams 141a of the first-type radiation are directed toward the patterned surface 125 of the photomask structure 120 by the light source 140). For example, as discussed in detail above with regard to the structure embodiments, if the primary first angle of incidence θ is 6 degrees, then equations (1)-(5) can be used to determine that the first beams of the first-type radiation and the second beams of the second-type radiation will primarily head in different directions if the tilt angle α is as small as 5 degrees (i.e., α≥5 degrees).

It should be noted than any suitable techniques of forming the pellicle frame 131 and attaching the pellicle 134 to the pellicle frame 131 and/or mounting the pellicle structure 130 to the photomask structure 120 could be used during the various process steps described above to ensure that the pellicle 134 is angled at the specific tilt angle α relative to the planar surface 126 of the photomask structure 120.

For example, FIGS. 3A-3B show different cross-section views of an exemplary photomask-pellicle apparatus 110A formed by mounting a pellicle structure 130 on a photomask structure 120 at process 606. In this case, the pellicle structure provided at process 604 includes a pellicle frame 131 that is customized so that a pellicle 134 attached to the pellicle frame 131 has a fixed tilt angle. Then, at process 606, the pellicle frame 131 is mounted directly onto the planar surface 126 of the photomask structure 120. FIGS. 4A-4B show different cross-section views of another exemplary photomask-pellicle apparatus 110B. In this case, the photomask structure 120 provided at process 602 includes a groove in the patterned layer 122 around the edge portion 123 of the photomask structure 120 and the pellicle structure 130 provided at process 604 includes a pellicle frame 131 that is customized so that a pellicle 134 attached to the pellicle frame 131 has a fixed tilt angle. Then, at process 606, the pellicle frame 131 is inserted into a groove and attached thereto. FIGS. 5A-5B show different cross-section views of another exemplary photomask-pellicle apparatus 110C formed at process 606. In this case, the pellicle structure 130 provided at process 602 is a standard pellicle structure. However, when the pellicle structure 120 is mounted onto the edge portion 123 of the photomask structure 120 at process 606, a combination of adhesive 505 and stud(s) 507 and/or shim(s) 506 are used to ensure that the specific tilt angle α for the pellicle 134 is achieved. Alternatively, although not shown, the pellicle structure 120 provided at process 604 could be formed using a combination of adhesive 505 and stud(s) 507 and/or shim(s) 506 to attach the pellicle 134 to the pellicle frame 131, thereby ensuring that the specific tilt angle α for the pellicle 134 will be achieved. Then, when the pellicle structure 120 is mounted on the photomask structure 120 at process 606, the pellicle frame 131 is mounted directly onto the planar surface 126 of the photomask structure 120. Alternatively, although not shown, a pellicle structure 130 could be provided at process 604 with a selectively adjustable tilt angle. It should be noted that the examples provided above are not intended to be limiting and that any other suitable techniques could be used when providing the photomask structure 120 and the pellicle structure 130 at processes 602-604 and/or when mounting the pellicle structure 130 on the photomask structure 120 at process 606 in order to form a photomask-pellicle apparatus 110, as described above, with an angled pellicle 134.

In any case, following the photolithographic exposure process, additional steps (e.g., conventional photosensitive layer development and feature layer etch processes) can be performed in order to transfer the exposure pattern from the photosensitive layer 151 into a feature layer 152 of the target semiconductor wafer 150 below (see process 610). By using a photomask-pellicle apparatus 110 with an angled pellicle 134 during the photolithographic exposure process, negative impacts on the exposure pattern in the photosensitive layer are minimized. As a result, critical dimension fails associated with shapes patterned into the feature layer at process 610 are also minimized.

It should be understood that the terminology used herein is for the purpose of describing the disclosed structures and methods and is not intended to be limiting. For example, as used herein, the singular forms “a”, “an” and “the” are intended to include the plural forms as well, unless the context clearly indicates otherwise. Additionally, as used herein, the terms “comprises” “comprising”, “includes” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right”, “left”, “vertical”, “horizontal”, “top”, “bottom”, “upper”, “lower”, “under”, “below”, “underlying”, “over”, “overlying”, “parallel”, “perpendicular”, etc., are intended to describe relative locations as they are oriented and illustrated in the drawings (unless otherwise indicated) and terms such as “touching”, “in direct contact”, “abutting”, “directly adjacent to”, “immediately adjacent to”, etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An apparatus comprising:
a photomask structure comprising: a center portion having a patterned surface; and an edge portion adjacent to a periphery of the center portion and having a planar surface; and
a pellicle structure comprising:
a pellicle frame; and
a pellicle attached to the pellicle frame,
wherein the pellicle is less reflective to a first-type radiation than to a second-type radiation that is different from the first-type radiation, and
wherein the pellicle frame is mounted on the photomask structure with the pellicle covering the patterned surface and being angled relative to the planar surface.

2. The apparatus of claim 1,
wherein, during a photolithographic exposure process, a light source generates first beams of the first-type radiation and second beams of the second-type radiation, and
wherein a predetermined tilt angle of the pellicle relative to the planar surface causes most of the first beams to pass through the pellicle, head toward the patterned surface at a range of first angles of incidence relative to the planar surface, be reflected off of the patterned surface at a range of first angles of reflection, pass back through the pellicle and head in a range of first directions, and causes most of the second beams to head toward the pellicle at a range of second angles of incidence relative to the pellicle, be reflected off of the pellicle at a range of second angles of reflection and head in a range of second directions that is different from the range of first directions.

3. The apparatus of claim 2,
wherein any first beams that are reflected off of the pellicle head in the range of second directions, and
wherein the tilt angle is predetermined such that a primary first direction in the range of first directions and a primary second direction in the range of second directions are non-parallel and overlap between the range of first directions and the range of second directions is at least reduced

4. The apparatus of claim 1, wherein the first-type radiation is radiation with a wavelength within an extreme ultraviolet radiation wavelength band and the second-type radiation is radiation with a wavelength outside the extreme ultraviolet radiation wavelength band.

5. The apparatus of claim 1, the first-type radiation has a wavelength of 13.5 nm and the second-type radiation has a wavelength that is greater than 13.5 nm.

6. The apparatus of claim 1, wherein the pellicle prevents particles from contaminating the patterned surface prior to and during a photolithographic exposure process.

7. The apparatus of claim 1,
wherein the frame comprises a first wall and a second wall opposite the first wall, and
wherein the first wall has a first height, the second wall has a second height that is greater than the first height, and the first wall is separated from the second wall by a predetermined distance such that the pellicle is angled and a specific tilt angle for the pellicle is achieved.

8. The apparatus of claim 1,
wherein the pellicle frame comprises: opposing walls having bottom surfaces and top surfaces opposite the bottom surfaces,
wherein the bottom surfaces are adhered to the planar surface of the photomask structure,
wherein the top surfaces are adhered to the pellicle, and
wherein the apparatus further comprises studs layered between any of the following to achieve a specific tilt angle for the pellicle:
between at least one bottom surface of at least one of the opposing walls and the planar surface of the photomask structure; and
between at least one top surface of at least one of the opposing walls and the pellicle.

9. A system comprising:
a light source that generates beams of radiation including first beams of a first-type radiation and second beams of a second-type radiation that is different from the first-type radiation; and
a photomask-pellicle apparatus comprising:
a photomask structure comprising: a planar substrate; and a patterned layer on the planar substrate, wherein a center portion of the photomask structure has a patterned surface and an edge portion adjacent to a periphery of the center portion has a planar surface that parallel to the planar substrate; and,
a pellicle structure comprising:
a pellicle frame; and
a pellicle attached to the pellicle frame,
wherein the pellicle is essentially transparent to the first-type radiation and is essentially reflective to the second-type radiation,
wherein the pellicle frame is mounted on the photomask structure with the pellicle covering the patterned surface and being angled relative to the planar surface, and
wherein a predetermined tilt angle of the pellicle relative to the planar surface is such that, during a photolithographic exposure process when the light source aims the beams of radiation at the photomask-pellicle apparatus, most of the first beams pass through the pellicle, head toward the patterned surface at a range of first angles of incidence, are reflected off of the patterned surface at a range of first angles of reflection, pass back through the pellicle and head in a range of first directions, and most of the second beams head toward the pellicle at a range of second angles of incidence, are reflected off of the pellicle at a range of second angles of reflection and head in a range of second directions that is different from the range of first directions.

10. The system of claim 9, wherein any of the first beams reflected off of the pellicle head in the range of second directions and wherein a primary second direction in the range of second directions is not parallel to a primary first direction in the range of first direction so as to at least reduce overlap between the range of first directions and the range of second directions.

11. The system of claim 9, wherein the first-type radiation is radiation with a wavelength within an extreme ultraviolet radiation wavelength band and the second-type radiation is radiation with a wavelength outside the extreme ultraviolet radiation wavelength band.

12. The system of claim 9, the first-type radiation has a wavelength of 13.5 nm wavelength and the second-type radiation has a wavelength that is greater than 13.5 nm.

13. The system of claim 9, wherein the pellicle prevents particles from contaminating the patterned surface prior to and during a photolithographic exposure process.

14. The system of claim 9,
wherein the pellicle frame comprises a first wall and a second wall opposite the first wall, and
wherein the first wall has a first height, the second wall has a second height that is greater than the first height, and the first wall is separated from the second wall by a predetermined distance such that the pellicle is angled and a specific tilt angle for the pellicle is achieved.

15. The system of claim 9,
wherein the pellicle frame comprises: opposing walls having bottom surfaces and top surfaces opposite the bottom surfaces,
wherein the bottom surfaces are adhered to the planar surface of the photomask structure,
wherein the top surfaces are adhered to the pellicle, and
wherein the apparatus further comprises any one of studs and shims layered between any of the following to achieve a specific tilt angle for the pellicle:
between at least one bottom surface of at least one of the opposing walls and the planar surface of the photomask structure; and
between at least one top surface of at least one of the opposing walls and the pellicle.

16. A method comprising:
providing a pellicle structure and a photomask structure,
wherein the photomask structure comprises a center portion having a patterned surface; and an edge portion adjacent to a periphery of the center portion and having a planar surface, and
wherein the pellicle structure comprises: a pellicle frame; and a pellicle attached to the pellicle frame, and
wherein the pellicle is essentially transparent to a first-type radiation and reflects a second-type radiation that is different from the first-type radiation;
mounting the pellicle structure on the photomask structure to form a photomask-pellicle apparatus with the pellicle covering the patterned surface and being angled relative to the planar surface; and
performing a photolithographic exposure process using the photomask-pellicle apparatus and a light source that generates first beams of the first-type radiation and second beams of the second-type radiation,
wherein, during the photolithographic exposure process, most of the first beams pass through the pellicle, head toward the patterned surface at a range of first angles of incidence, are reflected off of the patterned surface at a range of first angles of reflection, pass back through the pellicle and head in a range of first directions, and most of the second beams head toward the pellicle at a range of second angles of incidence, are reflected off of the pellicle at a range of second angles of reflection and head in a range of second directions that is different from the range of first directions.

17. The method of claim 16, further comprising, before the mounting of the pellicle structure and the performing of the photolithographic exposure process, predetermining the tilt angle to ensure that a primary first direction in the range of first directions and a primary second direction in the range of second directions are non-parallel and to at least reduce overlap between the range of first directions and the range of second directions.

18. The method of claim 16, wherein the range of first angles of incidence is 1 and 11 degrees and the tilt angle is at least 5 degrees.

19. The method of claim 16, wherein the first-type radiation is radiation with a wavelength within an extreme ultraviolet radiation wavelength band and the second-type radiation is radiation with a wavelength outside the extreme ultraviolet radiation wavelength band.

20. The method of claim 16, wherein the first-type radiation has a wavelength of 13.5 nm wavelength and the second-type radiation has a wavelength that is greater than 13.5 nm.
